(19) United States
(12) Patent Application Publication
(10) Pub. No.: US 2006/0134846 A1
(43) Pub. Date: Jun. 22, 2006

(54) Method of fabricating a semiconductor structure

(75) Inventor: Szu-Yu Wang, Shiaugang Chiu (TW)

Correspondence Address: MACRONIX;C/O HAYNES BEFFELL & WOLFELD LLP, P. O. BOX 366, HALF MOON BAY, CA, 94019, US

(73) Assignee: Macronix International Co., Ltd., Hsinchu (TW)

(21) Appl. No.: 11/013,829

(22) Filed: Dec. 16, 2004

(51) Int. Cl. H01L 21/8238; H01L 21/76

(52) U.S. Cl. 438/211

(57) ABSTRACT

A method of fabricating a semiconductor structure is disclosed. The method comprises the steps of: providing an intermediate structure, the intermediate structure comprising a substrate having an insulating layer thereon and an overlying gate structure; depositing an oxidation barrier layer on the intermediate structure; and exposing the oxidation barrier layer to a reactant which reduces defects in the oxidation barrier layer. The existence of the oxidation barrier layer helps to prevent oxide encroachment and edge oxide thickening of the insulating layer during subsequent processing.

### BACKGROUND OF THE INVENTION

1. Field of the Invention

The present invention relates to methods for fabricating a semiconductor structure. Embodiments of the present invention relate to methods for fabricating an oxidation barrier layer on a semiconductor structure.

2. Description of the Prior Art

In order to produce semiconductor devices, complex structures are typically formed and the dimensions and properties of those structures needs to be carefully controlled in order to ensure device reliability and predictability of that device's characteristics. In order to build up a complex structure, a number of fabrication processing steps are typically performed. Care must be taken to ensure that any processing steps which are performed do not undesirably affect the properties or characteristics of any semiconductor structures already formed.

One problem that exists is that polycrystalline regions in a semiconductor structure can become oxidized, either by contact with the atmosphere or during a subsequent processing step. For example, when forming a gate transistor, the polycrystalline gate overlying the oxide layer on the substrate can suffer from oxide encroachment and thickening at an edge corner of the polycrystalline gate. This oxide encroachment and thickening is caused by oxidation of the sidewall of the polycrystalline gate.

Oxide encroachment and edge oxide thickening can have a deleterious effect on the characteristics of devices being fabricated and can affect yield. For example, when fabricating gate transistors, as the amount of oxide encroachment increases, the channel length of the device is reduced. This results in a decreased active area and the read current of the device is reduced. In addition, the uniformity of the threshold voltage characteristics of the device will be affected. Oxide encroachment can also reduce the life of the device.

In one known fabrication technique, a furnace oxide process, oxide encroachment occurs. This process, with about 40 Angstroms silicon oxide grown on the polysilicon sidewall, results in induced reactant diffusion along the edge of the corner of the polygate and causes encroachment and edge oxide thickening of around 35 Angstroms. The high degree of oxide encroachment is thought to occur due to the long process time.

In another known fabrication technique, using a in-situ steam generation process (ISSG), an edge thickening of around 30 Angstroms can occur with the same thickness level of silicon oxide grown on polysilicon sidewall. This reduction in encroachment and edge oxide thickening is thought to be as a result of the shorter process time that ISSG sidewall oxidation requires.

In a further fabrication technique, which uses plasma oxidation, the encroachment and edge oxide thickening is further reduced, thought to be as a result of the lower process temperature.

U.S. Pat. No. 6,630,381 describes a fabrication technique for reducing encroachment and edge oxide thickening. The technique requires a thermal oxidation step followed by low-pressure tetraethyl orthosilicate chemical vapor deposition. However, the process of growing the thermal oxide by thermal oxidation is thought to inevitably result in some encroachment and thickening of the edge oxide. Also, a problem with this process is that these devices suffer from leakage. This leakage thought to be due to the poor quality of the oxide film produced by the chemical vapor deposition step, these oxide films usually have poorer quality than that grown by a thermal process. The poor quality is thought to be due to the high defect density in the deposited oxide film. Accordingly, a poor quality sidewall oxide film will result in a leakage current due to paths being created between the gate and the source or drain in which tunneling can occur through the oxide layer.

In many situations, oxide encroachment and edge oxide thickening is not a critical limitation. This is because, for relatively large devices, the reduction in effective channel length is negligible and has a limited effect on the performance of the device. However, oxide encroachment becomes an important factor when reducing the size of the devices. This is because as the size of the device is reduced the channel length of these smaller devices will also reduce, whilst the amount of oxide encroachment will typically remain relatively static. Accordingly, as the channel length reduces, the proportion of the channel which suffers from oxide encroachment will increase. This reduction in effective channel length can reduce the performance and yield of the devices to unacceptable levels. Also, it will be appreciated that as the sizes of devices are decreased, the problem of leakage current will become more significant.

It is desired to provide a technique which reduces the effects of oxide encroachment.

### SUMMARY OF THE INVENTION

Viewed from a first aspect, the present invention provides a method of fabricating a semiconductor structure, the method comprising the steps of: providing an intermediate structure, the intermediate structure comprising a substrate having an insulating layer thereon and an overlying gate structure; depositing an oxidation barrier layer on the intermediate structure; and exposing the oxidation barrier layer to a reactant which reduces defects in the oxidation barrier layer.

The inventors of the present invention recognize that the oxidation which causes oxide encroachment and oxide edge thickening in the insulating layer and gate structure is a result of two dominant factors in polycrystalline oxidation. These dominant factors are diffusion and surface reaction. The reactants need to diffuse to the polycrystalline surface first and then the oxidation can occur. The inventors recognize that the presence of available oxygen exacerbates edge oxide encroachment. Accordingly, the oxidation barrier layer is deposited on the intermediate structure. The intermediate structure comprises a substrate having the insulating layer and overlying gate structure. This oxidation barrier layer can be deposited on the intermediate structure without causing oxide encroachment or oxide edge thickening. The oxidation barrier layer is then exposed to a reactant which reduces the presence of any defects in the barrier layer. This barrier layer assists in the prevention of edge oxide encroachment or oxide edge thickening during subsequent processing by reducing the extent of diffusion of oxygen to the gate structure. Thereafter, the semiconductor structure may be subject to any number of subsequent processing steps to produce the final device. However, the existence of the oxidation barrier layer helps to prevent oxide encroachment and edge oxide thickening of the insulating layer during those subsequent processing steps.

In one embodiment, the reactant comprises an oxygen carrier and the step of exposing comprises exposing the oxidation barrier layer to the oxygen carrier at a temperature sufficient to reduce defects in the oxidation barrier layer.

Exposing the oxidation barrier layer to the oxygen carrier reduces defects in the oxidation barrier layer which prevents reactants from causing edge oxide encroachment or oxide edge thickening during subsequent processing.

In one embodiment, the reactant comprises an oxygen carrier and the step of exposing comprises annealing the oxidation barrier layer in the presence of the oxygen carrier to reduce hydrogen caused inclusions in the oxidation barrier layer.

The depositing of the oxidation barrier layer can result in the presence of hydrogen or hydroxyl (OH) inclusions. Annealing in the presence of an oxygen carrier helps to reduce such inclusions and assists in preventing reactants from causing edge oxide encroachment or oxide edge thickening during subsequent processing.

In one embodiment, the oxidation barrier layer prevents the diffusion of reactants into the insulating layer and the overlying gate structure.

In one embodiment, the oxidation barrier layer comprises an oxide layer.

In one embodiment, the oxide barrier layer comprises an insulation layer.

In one embodiment, the oxide barrier layer comprises at least one of silicon dioxide (SiO2), silicon oxynitride (SiOxNy), and aluminum oxide (Al2O3).

In one embodiment, the oxidation barrier layer has a thickness of less than about 200 Angstroms.

In one embodiment, the step of depositing comprises the step of depositing the oxidation barrier layer using low-pressure chemical vapor deposition.

In one embodiment, the low pressure chemical vapor deposition of the oxidation barrier layer is performed in the presence of TEOS (Tetraethyl Orthosilicate, Si(OC2H5)4), at a pressure of less than about 53 KPa (400 Torr) and at a temperature in the range of about 600 to 900 Celsius.

In one embodiment, the low pressure chemical vapor deposition of the oxidation barrier layer is performed in the presence of SiD4, SiH2Cl2, SiD2Cl2, SiHCl3, SiDCl3 or silane (SiH4) together with nitrous oxide (N2O) or oxygen (O2) at a pressure of less than about 53 KPa (400 Torr) and at a temperature in the range of about 700 to 900 Celsius.

In one embodiment, the low pressure chemical vapor deposition of the oxidation barrier layer is performed in the presence of silane (SiH4) and nitrous oxide (N2O), at a pressure of less than about 53 KPa (400 Torr) and at a temperature in the range of about 700 to 900 Celsius.

In one embodiment, the depositing step comprises the step of depositing the oxidation barrier layer using plasma enhanced chemical vapor deposition.

In one embodiment, the plasma enhanced chemical vapor deposition of the oxidation barrier layer is performed in the presence of silane (SiH4) and nitrous oxide (N2O), at a pressure of less than about 1.3 KPa (10 Torr) and at a temperature in the range of about 300 to 500 Celsius.

In one embodiment, exposing step comprises the step of oxidizing the oxidation barrier layer using wet oxidation.

In one embodiment, the wet oxidation is performed in the presence of hydrogen (H2) or deuterium (D2) and oxygen (O2) at a pressure of less than about 101 KPa (1 Atmosphere) and at a temperature in the range of about 750 to 1100 Celsius.

In one embodiment, the exposing step comprises the step of oxidizing the oxidation barrier layer using dry oxidation.

In one embodiment, the dry oxidation is performed in the presence of oxygen (O2) at a pressure of about 101 KPa (1 atmosphere) and at a temperature in the range of about 750 to 1100 Celsius.

In one embodiment, the exposing step comprises the step of oxidizing the oxidation barrier layer using O* radical oxidation.

In one embodiment, the O* radical oxidation is performed in the presence of hydrogen (H2) or deuterium (D2) and oxygen (O₂) at a pressure of less than about 13 KPa (100 Torr) and at a temperature in the range of about 850 to 1100 Celsius.

In one embodiment, the insulating layer and the gate structure comprise components of a CMOS or a memory device.

In one embodiment, the insulating layer and the gate structure define sidewalls extending away from the substrate.

In one embodiment, the step b) causes the oxidation barrier layer to be deposited on at least the sidewalls.

In one embodiment, the insulating layer comprises at least one of silicon dioxide (SiO2), silicon oxynitride (SiOxNy) and silicon nitride (Si3N4) or combinations or layers thereof.

In one embodiment, the gate structure comprises polysilicon.

Viewed from a second aspect, the present invention provides a method of forming a diffusion barrier on sidewalls of a gate transistor, the method comprising the steps of: providing a gate transistor comprising an insulating layer overlying a semiconductor substrate and a gate structure overlying the insulating layer, the floating gate transistor defining sidewalls extending away from the substrate; depositing an oxide layer on the floating gate transistor using a deposition process; and annealing the oxide layer to reduce defects in said oxide layer and to form the diffusion barrier which prevents the diffusion of reactants into the insulating layer and the overlying gate structure.

### BRIEF DESCRIPTION OF THE DRAWINGS

The present invention will be described further, by way of example only, with reference to embodiments thereof as illustrated in the accompanying drawings, in which:

FIG. 1 is a cross-sectional view of a gate structure;

FIG. 2 is a cross-sectional view of a gate structure having an oxidation barrier layer deposited thereon according to one embodiment;

FIG. 3 is a cross-sectional view of a gate structure in which the oxidation barrier layer has been subjected to a subsequent process to form a diffusion barrier layer according to one embodiment; and

FIG. 4 illustrates a method of fabricating a semiconductor structure according to one embodiment.

### DESCRIPTION OF EMBODIMENTS

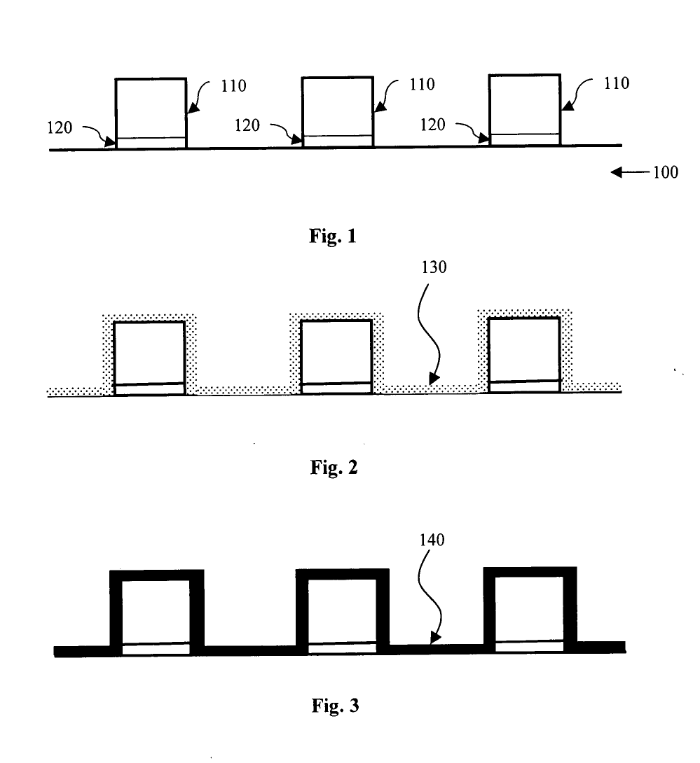

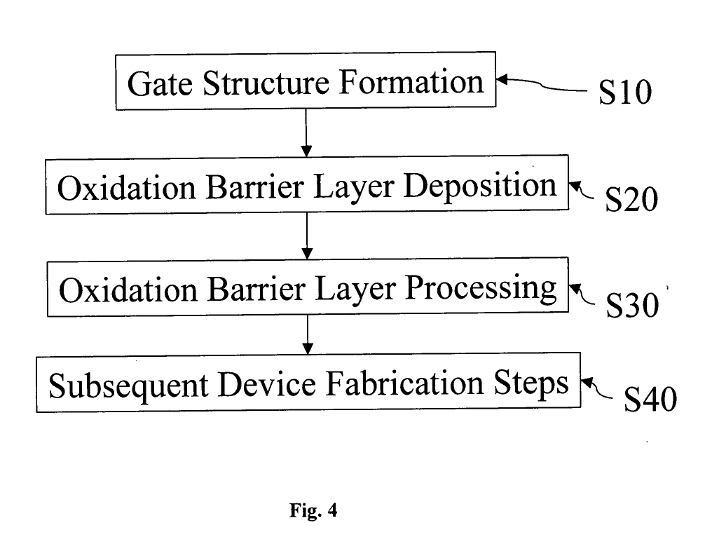

Embodiments of the present invention will now be described with reference to FIGS. 1 to 3 which illustrate a cross-sectional view of a gate structure formed by the fabrication method steps illustrated in FIG. 4, the gate structure having reduced oxide edge thickening and reduced edge oxide encroachment.

In contrast with the prior art approaches which use a process sequence of thermal oxidation on the gate structure followed by oxide layer deposition, the present technique, as will be described in more detail below, uses a reverse sequence of forming an oxide barrier layer followed by, for example, thermal oxidation. This provides for greater control over oxide encroachment than is possible by first performing thermal oxidation of the polysilicon sidewall and then performing oxide layer deposition. This is because the edge oxide encroachment and sidewall thickening is dominated by two main factors of the thermal oxidation process. These factors are diffusion and surface reaction. Before sidewall oxidation or edge oxide thickening can occur the reactants firstly need to diffuse to the silicon surface or interface. For the case of sidewall oxidation, surface reactions can occur on both the vertical sidewall and on the corner interface with the insulation oxide layer. The corner of the transistor structure has two silicon/oxide interfaces (one at the sidewall and the other at the interface of the polysilicon to the oxide insulating layer). The diffusion and combined surface reactions during thermal oxidation results in oxide encroachment.

By performing the oxide barrier layer deposition before performing thermal oxidation it has been found that the oxide barrier layer acts as a barrier layer to the reactants which cause edge encroachment or sidewall thickening to occur.

Also, the thermal oxidation helps to repair defects within the deposited oxide barrier film without causing edge oxide encroachment. By repairing defects the leakage current through the oxide barrier layer is also reduced.

Transistors formed by the present technique may be used in various different semiconductor devices such as general logic, volatile or non-volatile memories such as DRAM, FLASH or other integrated circuit transistor gate structures such as quantum-wire memory devices or CMOS devices.

Techniques for fabricating a gate structure having reduced oxide edge thickening and reduced edge oxide encroachment will now be described in more detail.

Firstly, at step S10, a gate structure is formed in accordance with conventional techniques known in the art in which a gate 110 and an insulating layer 120 pattern is defined on a substrate 100.

Materials suitable for the gate 110 include polysilicon, polycide, germanium (Ge), silicon germanium (SiGe) or SiGe:C. Materials suitable for the insulating layer 120 include silicon dioxide (SiO₂), silicon oxynitride (SiOxNy), silicon nitride (Si3N4), other insulators or a combination of these materials.

In an NROM memory device, the gate 110/insulating layer 120 structure includes a stack of silicon dioxide (SiO₂), silicon oxynitride (SiOxNy) and silicon dioxide (SiO₂), otherwise known as an ONO stack between the gate 110 and the substrate 100. Typically, the ONO stack comprises silicon oxynitride (SiOxNy) with variations in the silicon nitride (Si3N4) component so that it behaves as an ONO stack.

At step S20, an oxide barrier layer in the form of a oxide layer 130 is deposited on the patterned area, as shown in FIG. 2. The oxide layer 130 is silicon dioxide (SiO₂) having a thickness of less than about 200 Angstroms. The oxide layer 130 can include silicon oxynitride (SiOxNy) or other dielectrics such as aluminum oxide (Al₂O₃) which can benefit from the subsequent processing to improve the oxide layer 130 quality or any other insulator. The oxide layer 130 is deposited using low-pressure chemical vapor deposition, by high-density plasma processing or by plasma enhanced chemical vapor deposition.

In the low-pressure chemical vapor deposition technique, silane (SiH4) and nitrous oxide (N₂O) are introduced into a low-pressure chemical vapor deposition furnace or a low-pressure chemical vapor deposition chamber at a pressure of less than about 53 KPa (400 Torr) and at a temperature of between about 700° C. and 900° C. Alternatively, the deposition is performed in the presence of TEOS (Tetraethyl Orthosilicate, Si(OC2H5)4), at a pressure of less than about 53 KPa (400 Torr) and at a temperature of between about 600° C. and 900° C.

In the plasma enhanced chemical vapor deposition technique, the silicon dioxide (SiO₂) is first formed from the decomposition of injecting gases such as silane (SiH4) or other silicon-based gases and nitrous oxide (N₂O) at a pressure of about less than 1.3 KPa (10 Torr) and at a temperature in the range of about 300° C. to 500° C. The silane (SiH4) can be replaced with SiD₄, SiH₂Cl₂, SiD₂Cl₂, SiHCl₃ or SiDCl₃. The nitrous oxide can also be replaced by oxygen.

As mentioned previously the quality of low-temperature oxide films produced by chemical vapor deposition techniques such as low-pressure chemical vapor deposition or plasma enhanced chemical vapor deposition is usually lower than that of a conventionally thermally grown oxide film. This is due to the high defect density caused by vacancies, dangling bonds, impurities, inclusions etc. in the chemical vapor deposition oxide film (such as those caused by hydrogen, hydroxyl or other inclusion or impurities). The defects will result in a high leakage current through the oxide layer.

The oxide layer 130, which is fabricated using low-pressure chemical vapor deposition or plasma enhanced chemical vapor deposition, will suffer from such defects.

At step S30, the oxide layer 130 is exposed to a reactant and the characteristics of the oxide layer 130 change to form the diffusion barrier layer 140, as illustrated in FIG. 3. The diffusion barrier layer 140 is formed by subjecting the oxide layer 130 to a thermal densification process or annealing process in the presence of oxygen or O* radicals, which oxidizes the oxide layer 130 or by implanting oxygen atoms followed by thermal annealing. The oxide layer 130 acts as a buffer layer to prevent oxide encroachment or edge oxide thickening during this subsequent thermal processing.

This processing can be performed using a variety of techniques (such as wet oxidation, dry oxidation, O* radical oxidation or plasma oxidation), using existing fabrication tooling widely used in semiconductor fabrication for dielectric film formation. Such tooling includes an AP furnace, a rapid thermal oxidation chamber (such as an in-situ steam generator) or a low pressure furnace used for radical oxidation.

In a first technique, wet oxidation occurs at a pressure of around 101 KPa (1 atmosphere) and at a temperature of about 750° C. to 1100° C. in the presence of hydrogen or deuterium, together with oxygen (H2 (or D2)+O2->H2O (or D20)), in a rapid thermal oxidation chamber or furnace. The ratio of hydrogen to hydrogen and oxygen (H2/(H2+O2)) is up to 60%. It will be appreciated than other oxygen-based gases like nitrous oxide and nitric oxide may also be used.

In a second technique, dry oxidation occurs using pure oxygen or oxygen diluted with an inert gas like nitrogen at a pressure of around 101 KPa (1 atmosphere) and at a temperature of between 750° C. and 1100° C. in a rapid thermal processing chamber or furnace.

In a third technique, radical oxidation occurs using hydrogen or deuterium plus oxygen to produce oxygen and OH or OD radicals (H2 (or D2)+O2->O*+OH* (or OD*)). The radical oxidation is performed in a rapid thermal processing chamber such as an in-situ steam generation chamber at a pressure of less than about 13 KPa (100 Torr), a temperature of between about 850° C. and 1100° C. The ratio of hydrogen to hydrogen and oxygen (H2/(H2+O2)) is up to about 40%.

The defects in the oxide layer 130 are reduced by oxygen binding during this subsequent thermal oxidation step. By performing additional oxidation following the deposition of the oxide layer 130 on the transistor sidewalls, defects in the oxide layer 130 are repaired which reduces defect density in the diffusion barrier layer 140. This clearly has a number of advantages as the sizes of devices are reduced because the distance between the sidewall of the gate 110 and insulating layer 120 structure and the source or drain of the transistor or a conducting plug will also be reduced. Accordingly, the improvement in the quality of the oxide layer 130 when forming the diffusion barrier layer 140 reduces the extent of leakage current through the diffusion barrier layer 140. Also, by reducing edge oxide encroachment and oxide thickening, the effective channel lengths of these reduced size devices will be maintained and thus higher drain current can be achieved. Furthermore, the threshold distribution of the devices is more consistent.

Thereafter, at step S40, the structure can be subject to any number of subsequent processing steps required to fabricate the final device. It will be appreciated that the presence of the diffusion barrier layer 140 will help to prevent edge oxide encroachment or oxide thickening occurring during these subsequent processing steps.

Accordingly, it will be appreciated that the present technique is particularly suited to a wide range of devices such as CMOS devices and advanced memory devices such as quantum memory devices. In particular, the present technique is particularly suited to memory devices which include mask ROM, DRAM, SRAM, EPROM or flash devices (having various types of gate structures such as floating gate, SONOS, NROM, quantum dot, quantum wire) or other structures consisting of at least a gate insulator and gate electrode sidewalls. Furthermore, the present technique is also useful in system-on-a-chip (SOC) devices.

Although a particular embodiment of the invention has been described herein, it will be apparent that the invention is not limited thereto, and that many modifications and additions may be made within the scope of the invention. For example, various combinations of the features of the following dependent claims could be made with the features of the independent claims without departing from the scope of the present invention.

I claim:

1. A method of fabricating a semiconductor structure, said method comprising the steps of:
providing an intermediate structure, the intermediate structure comprising a substrate having an insulating layer thereon and an overlying gate structure;
depositing an oxidation barrier layer on the intermediate structure; and
exposing said oxidation barrier layer to a reactant which reduces defects in said oxidation barrier layer.

2. The method of claim 1, wherein said reactant comprises an oxygen carrier and said exposing step comprises exposing said oxidation barrier layer to said oxygen carrier at a temperature sufficient to reduce defects in said oxidation barrier layer.

3. The method of claim 1, wherein said reactant comprises an oxygen carrier and said exposing step comprises annealing said oxidation barrier layer in the presence of said oxygen carrier to reduce hydrogen inclusions in said oxidation barrier layer.

4. The method of claim 1, wherein said oxidation barrier layer prevents the diffusion of reactants into said insulating layer and said overlying gate structure.

5. The method of claim 1, wherein said oxidation barrier layer comprises an oxide layer.

6. The method of claim 5, wherein said oxide layer comprises an insulation layer.

7. The method of claim 5, wherein said oxide layer comprises at least one of silicon dioxide (SiO2), silicon oxynitride (SiOxNy) and aluminum oxide (Al2O3).

8. The method of claim 1, wherein said oxidation barrier layer has a thickness of less than about 200 Angstroms.

9. The method of claim 1, wherein said depositing step comprises the step of depositing said oxidation barrier layer using low pressure chemical vapor deposition.

10. The method of claim 9, wherein said low pressure chemical vapor deposition of said oxidation barrier layer is performed in the presence of TEOS (Tetraethyl Orthosilicate, Si(OC2H5)4), at a pressure of less than about 53 KPa (400 Torr) and at a temperature in the range of about 600 to 900 Celsius.

11. The method of claim 9, wherein said low pressure chemical vapor deposition of said oxidation barrier layer is performed in the presence of SiD4, SiH2Cl2, SiD2Cl2, SiHCl3, SiDCl3 or silane (SiH4) together with nitrous oxide (N2O) or oxygen (O2) at a pressure of less than about 53 KPa (400 Torr) and at a temperature in the range of about 700 to 900 Celsius.

12. The method of claim 9, wherein said low pressure chemical vapor deposition of said oxidation barrier layer is performed in the presence of silane (SiH4) and nitrous oxide (N2O), at a pressure of less than about 53 KPa (400 Torr) and at a temperature in the range of about 700 to 900 Celsius.

13. The method of claim 1, wherein said depositing step comprises the step of depositing said oxidation barrier layer using plasma enhanced chemical vapor deposition.

14. The method of claim 11, wherein said plasma enhanced chemical vapor deposition of said oxidation barrier layer is performed in the presence of silane (SiH4) and nitrous oxide (N2O), at a pressure of less than about 1.3 KPa (10 Torr) and at a temperature in the range of about 300 to 500 Celsius.

15. The method of claim 1, wherein said exposing step comprises the step of oxidizing said oxidation barrier layer using wet oxidation.

16. The method of claim 15, wherein said wet oxidation is performed in the presence of hydrogen (H2) or deuterium (D2) and oxygen (O2) at a pressure of less than about 101 KPa (1 Atmosphere) and at a temperature in the range of about 750 to 1100 Celsius.

17. The method of claim 1, wherein said exposing step comprises the step of oxidizing said oxidation barrier layer using dry oxidation.

18. The method of claim 17, wherein said dry oxidation is performed in the presence of oxygen (O2) at a pressure of less than about 101 KPa (1 atmosphere) and at a temperature in the range of about 750 to 1100 Celsius.

19. The method of claim 1, wherein said exposing step comprises the step of oxidizing said oxidation barrier layer using O* radical oxidation.

20. The method of claim 19, wherein said O* radical oxidation is performed in the presence of hydrogen (H2) or deuterium (D2) and oxygen (O2) at a pressure of less than about 13 KPa (100 Torr) and at a temperature in the range of about 850 to 1100 Celsius.

21. The method of claim 1, wherein said insulating layer and said gate structure comprise components of a CMOS or a memory device.

22. The method of claim 1, wherein said insulating layer and said gate structure define sidewalls extending away from said substrate.

23. The method of claim 22, wherein said depositing step causes said oxidation barrier layer to be deposited on at least said sidewalls.

24. The method of claim 1, wherein said insulating layer comprises at least one of silicon dioxide (SiO2), silicon oxynitride (SiOxNy) and silicon nitride (Si3N4) or combinations or layers thereof.

25. The method of claim 1, wherein said gate structure comprises polysilicon.

26. A method of forming a diffusion barrier on a sidewall of a gate transistor, said method comprising the steps of:
providing a gate transistor comprising at least an insulating layer overlying a semiconductor substrate and a gate structure overlying said insulating layer, said gate transistor defining sidewalls extending away from said substrate;
depositing an oxide layer on the gate transistor using a deposition process; and
annealing the oxide layer to reduce defects in said oxide layer and to form said diffusion barrier which prevents the diffusion of reactants into said insulating layer and said overlying gate structure.
